(19) United States
(12) Patent Application Publication
(10) Pub. No.: US 2021/0090912 A1
(43) Pub. Date: Mar. 25, 2021

(54) ETCHING APPARATUS AND ETCHING METHOD

(71) Applicant: Tokyo Electron Limited, Tokyo (JP)

(72) Inventors: Naoki SHINDO, Nirasaki City (JP); Ryo KUWAJIMA, Nirasaki City (JP); Satoshi TODA, Nirasaki City (JP)

(21) Appl. No.: 17/016,872

(22) Filed: Sep. 10, 2020

(30) Foreign Application Priority Data
Sep. 20, 2019 (JP) 2019-172078

(51) Int. Cl. H01L 21/67; H01L 21/687

(52) U.S. Cl. CPC H01L 21/67069; H01L 21/68757

(57) ABSTRACT

An etching apparatus includes: a processing container configured to be evacuated to form a vacuum atmosphere in the processing container and including a wall that has an alloy composed of aluminum and an additive metal as a base material; a stage installed in the processing container and configured to mount a substrate having a metal film formed on a surface of the substrate; a gas supplier installed in the processing container and configured to supply an oxidizing gas that oxidizes the metal film and an etching gas that is β-diketone to the stage to etch the oxidized metal film; and a wall heater configured to heat the wall to a temperature in a range of 60 degrees C. to 90 degrees C. when the etching gas is supplied from the gas supplier into the processing container.

### CROSS-REFERENCE TO RELATED APPLICATION

This application is based upon and claims the benefit of priority from Japanese Patent Application No. 2019-172078, filed on Sep. 20, 2019, the entire contents of which are incorporated herein by reference.

### TECHNICAL FIELD

The present disclosure relates to an etching apparatus and an etching method.

### BACKGROUND

In a semiconductor device manufacturing process, a semiconductor wafer (hereinafter, referred to as a “wafer”), which is a substrate, is mounted on a stage within a processing container and is subjected to various kinds of processing, such as etching and film formation. For example, Patent Document 1 discloses an apparatus for etching a silicon oxide film on a wafer surface using hydrogen fluoride gas and ammonia gas, in which it is described that various components that constitute the apparatus, such as a chamber (processing container) and a placement stage (stage), are made of Al (aluminum).

On the inner surface of the chamber in the apparatus of Patent Document 1, pure Al not subjected to surface oxidation treatment is exposed in order to prevent hydrogen fluoride gas from adhering and remaining thereon. In addition, since the surface of the placement stage of the apparatus may be subjected to friction or impact when a wafer is mounted thereon, the surface of the placement stage is subjected to surface oxidation treatment so that an oxide film is formed thereon.

### PRIOR ART DOCUMENT

### Patent Document

Patent Document 1: International Publication Pamphlet No. WO 2007/72708 A1

### SUMMARY

According to one embodiment of the present disclosure, an etching apparatus includes: a processing container configured to be evacuated to form a vacuum atmosphere in the processing container and including a wall that has an alloy composed of aluminum and an additive metal as a base material; a stage installed in the processing container and configured to mount a substrate having a metal film formed on a surface of the substrate; a gas supplier installed in the processing container and configured to supply an oxidizing gas that oxidizes the metal film and an etching gas that is β-diketone to the stage to etch the oxidized metal film; and a wall heater configured to heat the wall to a temperature in a range of 60 degrees C. to 90 degrees C. when the etching gas is supplied from the gas supplier into the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view of an etching apparatus according to an embodiment of the present disclosure.

FIG. 2 is a vertical cross-sectional view of the etching apparatus.

FIG. 3 is a perspective view illustrating a partition wall forming member provided in the etching apparatus.

FIG. 4 is a view illustrating the action of the etching apparatus.

FIG. 5 is a vertical cross-sectional view illustrating another configuration of the etching apparatus.

FIG. 6 is a graph showing the results of an evaluation test.

FIG. 7 is a graph showing the results of an evaluation test.

FIG. 8 is a graph showing the results of an evaluation test.

FIG. 9 is a graph showing the results of an evaluation test.

FIG. 10 is a graph showing the results of an evaluation test.

FIG. 11 is a graph showing the results of an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An etching apparatus 1 according to an embodiment of the present disclosure will be described. The etching apparatus 1 is an apparatus for etching a metal film formed on the surface of a wafer W, such as a cobalt (Co) film. The etching apparatus 1 supplies nitric oxide (NO) gas as an oxidizing gas to oxidize the Co film, and also supplies hexafluoroacetylacetone (Hfac) gas, which is a β-diketone, to etch the oxidized Co film. The Hfac is also called 1,1,1,5,5,5-hexafluoro-2,4-pentanedione. Further, the etching apparatus 1 supplies hydrogen (H₂) gas as a reducing gas to the wafer W before supplying the NO gas and the Hfac gas to remove the natural oxide film formed on the surface of the Co film. The Hfac gas, the NO gas, and the H₂ gas are supplied to the wafer W together with nitrogen (N₂) gas, which is a carrier gas.

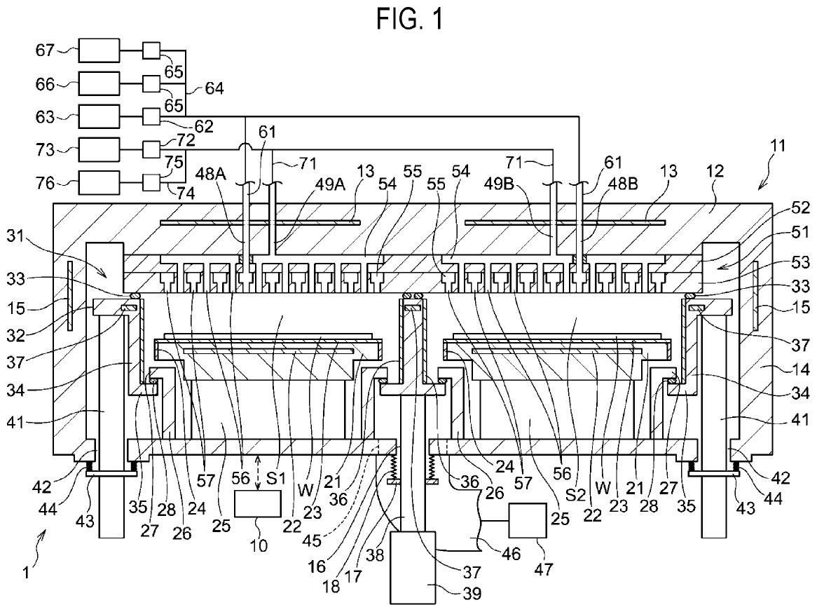

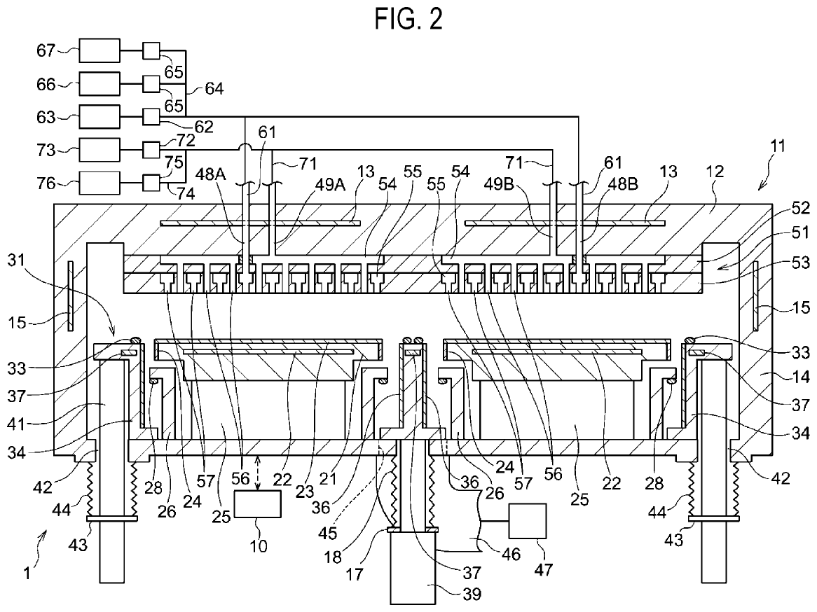

The etching apparatus 1 is provided with a processing container 11, and two wafers W can be accommodated and processed in a batch in the processing container 11. In order to suppress the consumption of each gas in performing such processing, a region in which each gas is supplied in the processing container 11 is limited by a vertically movable partition wall forming member 31 (described below) installed in the processing container 11. Hereinafter, a description will be given with reference to FIGS. 1 and 2, which are vertical cross-sectional views of the etching apparatus 1. FIGS. 1 and 2 illustrate states in which the partition wall forming member 31 is located at a raised position and a lowered position, respectively. The etching apparatus 1 is configured to prevent metal contamination of the wafer W by each member constituting the etching apparatus 1.

Since the base material of the wall of the processing container 11 is composed of an aluminum (Al) alloy containing Mg (magnesium) as a main additive metal due to advantages such as easy processing and sufficient strength. Specifically, the Al alloy is, for example, a JIS standard A5000 series alloy (A5000-family), and more specifically, for example, JIS standard A5052. The ceiling wall, which is a wall portion of the processing container 11, is constituted with a ceiling plate 12 and a shower head 51 provided below the ceiling plate 12. A ceiling heater 13 is embedded in the ceiling plate 12, and heats the ceiling plate 12 and the shower head 51 to a desired temperature. The configuration of the shower head 51, which is a gas supplier, will be described below. A side wall heater 15 is embedded in the side wall 14, which is a wall portion of the processing container 11, and heats the side wall 14 to a desired temperature. The ceiling heater 13 and the side wall heater 15 constitute a wall heater.

A stage 21 is installed in the processing container 11. Like the base material of the processing container 11, the base material of the stage 21 is also composed of an Al alloy containing Mg as a main addition metal so as to obtain sufficient strength, for example, the above-mentioned JIS standard A5000 series alloy, and more specifically, for example, A5052. Two circular stages 21 are installed side by side, and a wafer W is horizontally mounted on each of the stages 21. A stage heater 22 is embedded in each stage 21 so as to heat the mounted wafer W.

The top surface of each stage 21 is covered with a top surface cover 23, which is a top surface covering portion made of silicon (Si). The side surface of each stage 21 is covered with a side surface cover 24, which is a side surface covering portion made of a JIS standard A1000 series, that is, a material in which 99% or more of the content is aluminum and which is called pure aluminum. More specifically, the side surface cover 24 is made of, for example, JIS standard A1050. The top surface cover 23 and the side surface cover 24 are configured as a stage covering portion. Each stage 21 is supported on the bottom of the processing container 11 by a support 25. The stage 21 is provided with lifting pins that protrude and retract on the stage 21 so as to deliver a wafer W between the stage 21 and a transport mechanism. However, an illustration of the lifting pins is omitted.

An upstanding cylindrical inner wall 26 is installed so as to extend upward from the bottom wall of the processing container 11 and to surround the support 25. A flange 27 is formed at the upper end of the inner wall 26, and an annular seal member 28 is installed below the flange 27 along the circumference of the flange 27. In the lower portion of the side wall of the inner wall 26, a slit (not illustrated) is open so as to make the inside and the outside of the inner wall 26 communicate with each other.

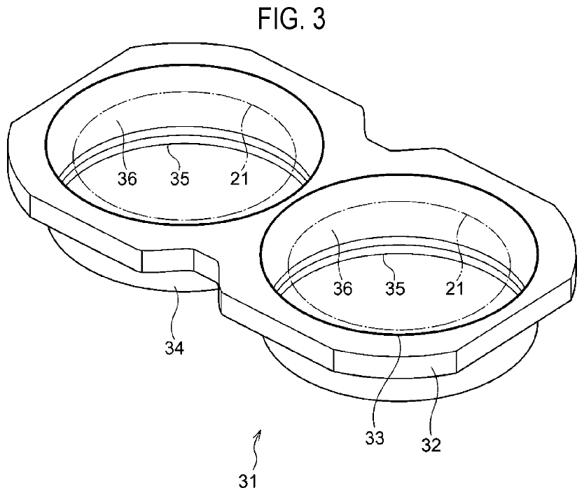

Next, the partition wall forming member 31 will be described with reference to FIG. 3, which is a perspective view. The partition wall forming member 31 has a shape in which, in two upstanding cylinders, the upper ends of which form flanges, respectively, the flanges of the cylinders are laterally connected to each other, portions of the side walls of the cylinders are laterally connected to each other, and each cylinder is located to surround the stage 21 and the inner wall 26. The flanges connected to each other are denoted by reference numeral 32, and an annular seal member 33 is installed on the flange 32 along the opening of each cylinder. Further, the side wall of each cylinder is defined as a partition wall 34. The lower end of the partition wall 34 protrudes to the inside of the cylinder to form an annular lower protrusion 35 located below the flange 27 of the inner wall 26.

The partition wall forming member 31 forms processing spaces S1 and S2 for processing wafers W as described below. The partition wall forming member 31 is required to have relatively high strength in order to prevent the occurrence of failure in a lifting operation and the occurrence of abnormal processing of wafers W, which may be caused when the partition wall forming member 31 is deformed by the pressure of the gas supplied to the processing spaces S1 and S2. Therefore, like the base material of the processing container 11, the base material of the partition wall forming member 31 is also composed of an Al alloy containing Mg as a main addition metal, for example, the above-mentioned JIS standard A5000 series alloy, more specifically, for example, A5052. The inner peripheral surfaces of the partition walls 34 are formed of a coating film 36, which is a vapor-deposited film of silicon that covers the base material. A partition wall heater 37, which is a heater for a wall, is embedded in the flange 32, and thus the partition wall forming member 31 can be heated to a desired temperature.

A driving shaft 38 is connected to the joint portion of the two cylinders of the partition wall forming member 31 from the lower side. The lower end of the driving shaft 38 is connected to a lifting mechanism 39 installed outside the processing container 11 through a through hole 16 that opens in the bottom of the processing container 11, and thus the partition wall forming member 31 moves between a raised position and a lowered position. In order to ensure the airtightness inside the processing container 11, a flange 17 installed on a portion of the driving shaft 38 outside the processing container 11 and an opening edge of the through hole 16 are connected by a bellows 18.

The raised position of the partition wall forming member 31 is the position thereof when the wafers W are processed. At this raised position, the lower protrusions 35 of the partition wall forming member 31 come into close contact with the flanges 27 of the inner walls 26 via the seal members 28, and the flanges 32 of the partition wall forming members 31 come into close contact with the shower head 51 forming the ceiling wall of the processing container 11 via the seal members 33. Therefore, when the partition wall forming member 31 is located at the raised position, the partition walls 34 extend downward from the ceiling wall of the processing container 11 to surround the stages 21, and form processing spaces S1 and S2, which are surrounded by the partition walls 34, respectively and are partitioned from each other. On the other hand, the lowered position of the partition wall forming member 31 is a position when the wafers W are delivered between the stages 21 and the transport mechanism, and the flange 32 is located at substantially the same height as the stages 21 so as not to hinder the delivery.

A plurality of guide shafts 41 is connected to the flange 32 to guide the rising and lowering of the partition wall forming member 31 from below, and the lower end of each guide shaft 41 passes through a through hole 42 that opens in the bottom of the processing container 11. In order to ensure the airtightness inside the processing container 11, a flange 43 installed on a portion of each of the guide shafts 41 outside the processing container 11 and an opening edge of the through hole 42 are connected by a bellows 44.

An exhaust port 45 shared by the processing spaces S1 and S2 is opened at a position apart from the processing spaces S1 and S2, and in the central portion of the bottom of the processing container 11 in a left-right direction, and the downstream end of an exhaust pipe 46 connected to the exhaust port 45 is connected to an exhaust mechanism 47 including, for example, a valve and a vacuum pump. The inside of the processing container 11 is evacuated by the exhaust mechanism 47 so as to have a vacuum atmosphere having a desired pressure. At that time, the processing spaces S1 and S2 are evacuated through the slits (not illustrated) formed in the inner walls 26.

The ceiling plate 12 of the processing container 11 will be further described. The ceiling plate 12 is installed with flow paths 48A, 49A, 48B, and 49B for supplying gas to the shower head 51, and these flow paths are partitioned from each other. The flow paths 48A and 49A introduce gas into the processing space S1, and the flow paths 48B and 49B introduce gas into the processing space S2. The shower head 51 is connected to the downstream sides of these flow paths 48A, 49A, 48B, and 49B, and forms flow paths partitioned from each other.

The shower head 51 is installed so as to face each stage 21, and includes an upper plate 52 and a lower plate 53, which are stacked on each other. The upper plate 52 and the lower plate 53 are made using, for example, a JIS standard A1000 series, specifically, for example, A1050, as a base material. In the left and right portions of the upper plate 52, recesses that are open to the upper side are formed, and each recess is closed by the ceiling plate 12 to form a gas diffusion space 54. In the left and right portions of the lower plate 53, recesses that are open to the upper side are formed, and each recess is closed by the upper plate 52 to form a gas diffusion space 55. Therefore, the shower head 51 includes upper and lower diffusion spaces for two stages. In the shower head 51, a large number of ejection holes 56 and a large number of ejection holes 57, which communicate with the diffusion spaces 54 and 55, respectively, are formed in the vertical direction. The ejection holes 56 and 57 are open in a region surrounded by the partition walls 34, and gas is ejected from the ejection holes 56 and the ejection holes 57 into the processing spaces S1 and S2, respectively.

In the upper portion of the ceiling plate 12, the downstream ends of gas supply pipes 61 are installed and connected to the gas flow paths 48A and 48B, respectively. Then, the upstream sides of the gas supply pipes 61 join each other and are connected, via a gas supply device 62, to a Hfac gas supply source 63 constituted with, for example, a gas cylinder, which is an etching gas reservoir. In addition, each of the gas supply device 62 and other gas supply devices described below includes, for example, a valve or a mass flow controller.

The gas supply pipe 61 is made of a base material of Hastelloy, that is, an alloy containing Ni (nickel), Cr (chrome), and Mo (molybdenum) as main constituent metals. In the gas supply device 62, the portion forming a flow path of the Hfac gas is also made of Hastelloy. With such a configuration, for example, 95% or more of the wall forming the gas flow passages from the connection between the Hfac gas supply source 63 and the gas supply pipes 61 to the inlets of the gas flow paths 48A and 48B is made of Hastelloy. The portion of the wall forming the gas flow path that is not formed of Hastelloy is a portion that is formed of, for example, a gasket. The gas supply pipes 61 are heated to 60 degrees C. to 100 degrees C., for example, by a heater (not illustrated) installed outside the pipe during the processing of wafers W in order to prevent liquefaction of the Hfac gas flowing in the pipes.

The downstream end of the gas supply pipe 64 is connected to the gas supply pipes 61 at an upstream side of a position where the above-mentioned two gas supply pipes 61 join. The upstream side of the gas supply pipe 64 is branched into two, and the upstream ends thus branched are connected to an NO gas supply source 66 and an N₂ gas supply source 67 via gas supply devices 65, respectively.

Further, in the upper portion of the ceiling plate 12, the downstream ends of gas supply pipes 71 are connected to the gas flow paths 49A and 49B, respectively. The upstream sides of the gas supply pipes 71 join with each other and are connected to an H₂ gas supply source 73 via a gas supply device 72. Further, a downstream end of a gas supply pipe 74 is connected to the gas supply pipe 71 on the upstream side of the position where the two gas supply pipes 71 described above join. The upstream side of the gas supply pipe 74 is connected to an N₂ gas supply source 76 via a gas supply device 75.

The gas supply pipes 64, 71, and 74 are made of, for example, stainless steel (SUS), which is less expensive than Hastelloy. Therefore, among the pipes provided in the etching apparatus 1 to supply gases, only limited portions of the gas supply pipes 61 forming the flow paths of the Hfac gas are made of Hastelloy, whereby the cost of manufacturing the apparatus can be reduced.

Hereinafter, the reason why the gas supply pipes 61, which are the flow path formation portion, are made of Hastelloy will be described. When the pipes forming the flow paths of Hfac gas are made of SUS, the amount of Fe (iron) adheres to wafers W increases, as shown in the evaluation tests described below. It is considered that this is because the Hfac gas reacts with Fe forming the gas supply pipes 61 to form Fe(Hfac)₂, which is a complex having a relatively high vapor pressure. That is, the gas supply pipes 61 are heated in order to prevent liquefaction of the Hfac gas flowing as described above. However, the Fe(Hfac)₂ is vaporized and released from the gas supply pipes 61 in the temperature band obtained by heating the same, thereby being supplied to the wafers W. Therefore, in the etching apparatus 1, Hastelloy, having an Fe content lower than that of SUS, is used for the gas supply pipes 61 so as to suppress the contamination of the wafers W by Fe. Further, as shown in the evaluation tests described below, it has been confirmed that, when the gas supply pipes 61 are made of Hastelloy, nickel (Ni) contamination of wafers W is also suppressed compared with the case where the gas supply pipes 61 are made of SUS.

As illustrated in FIG. 1, the etching apparatus 1 includes a controller 10. The controller 10 is configured with a computer, and has a program. The program incorporates a step group such that a series of operations described below can be performed in the etching apparatus 1 so as to perform etching. Based on the program, the controller 10 outputs a control signal to each part of the etching apparatus 1 so as to control the operation of each part. Specifically, each of operations, such as the adjustment of the supply and the flow rate of each gas by the gas supply device, the adjustment of the output of each heater, and the adjustment of the exhaust amount by the exhaust mechanism 47, is controlled by the control signal. The above-mentioned program is stored in a non-transitory storage medium such as a compact disc, a hard disc, or a DVD, and is installed in the controller 10.

As described above, the processing container 11 is composed of A5052, which is an Al alloy containing Mg. As shown in the evaluation tests described below, in a member formed of this alloy, as the temperature increases, Mg moves to the surface of the member and thus the amount of Mg on the surface increases. That is, by heating the wall of the processing container 11, the amount of Mg on the inner wall surface of the processing container 11 increases. Mg reacts with Hfac gas to form Mg(Hfac)₂, which is a complex having a relatively high vapor pressure. When a large amount of Mg moves to the inner wall surface of the processing container 11 as described above, a large amount of Mg(Hfac)₂ is generated. Accordingly, when the temperature of the wall of the processing container 11 is high, this Mg(Hfac)₂ may be vaporized and released from the wall of the processing container 11 and supplied to the wafers W, such that the wafers W will be contaminated with Mg.

The vapor pressure of Mg(Hfac)₂ changes comparatively greatly when the temperature changes in the range of 160 degrees C. or lower. For example, it is considered that the vapor pressure near 90 degrees C. is about 1/100 of the vapor pressure near 140 degrees C. Accordingly, by setting the temperature of the processing container 11 during the processing of the wafers W to a relatively low temperature, the release of the Mg(Hfac)₂ gas from the inner wall surface of the processing container 11 is greatly suppressed, and thereby the adhesion of Mg to the wafers W can be suppressed. However, when the temperature of the wall of the processing container 11 is too low, Hfac gas brought into contact with the wall is liquefied, and the wafers W cannot be processed. Therefore, when the Hfac gas is supplied into the processing container 11, the ceiling plate 12 and the shower head 51, which form the side wall 14 and the ceiling wall of the processing container 11, are heated to, for example, a temperature higher than the boiling point of Hfac at the pressure inside the processing container 11. In order to prevent the adhesion of Mg to the wafers W and prevent the liquefaction of the Hfac gas, the ceiling plate 12 and the side wall 14 are heated to 60 degrees C. to 90 degrees C. when the Hfac gas is supplied. That is, the ceiling heater 13 and the side wall heater 15 generate heat so as to reach 60 degrees C. to 90 degrees C.

The side wall 14 and the ceiling wall of the processing container 11 can be set to such a relatively low temperature during processing at positions relatively distant from the wafers W. However, like the processing container 11, each stage 21, the base material of which is made of A5052, needs to be heated to a relatively high temperature in order to ensure the reactivity between a wafer W mounted thereon and each gas supplied thereto. Specifically, during processing of the wafer W, the stage 21 is heated to, for example, 150 degrees C. to 250 degrees C. Therefore, the stage 21 is configured to be covered with the top surface cover 23 and the side surface cover 24, as described above. That is, the stage 21 is configured such that the supply of Hfac gas to the base material of A5052 is suppressed, the generation of Mg(Hfac)₂ is suppressed, and the release of Mg(Hfac)₂ gas to the wafer W is suppressed.

As shown in the evaluation tests described below, when a covering portion that covers the base material is made of A1050, it is possible to more effectively prevent Mg contamination. Therefore, the side surface cover 24 is made of A1050. The top surface cover 23 may be made of A1050, like the side surface cover 24, instead of being made of Si. However, since the side surface cover 23 is repeatedly brought into contact with wafers W when sequentially transporting the wafers W to the apparatus, the side surface cover 23 may have higher strength. From this viewpoint, the side surface cover 23 may be made of Si.

The base material of the support 25 and the inner wall 26, which support the stage 21, is made of, for example, A5052, and the base material is not covered. Thus, the base material of the support 25 and the inner wall 26 is exposed to Hfac gas when processing a wafer W. However, the support 25 and the inner wall 26 are located downstream of the wafer W in view of the gas flow within the processing container 11. Accordingly, even if Mg is released as Mg(Hfac)₂ gas from the support 25 and the inner wall 26, the released Mg is prevented from adhering to the wafer W.

The partition wall forming member 31 is located relatively close to the stages 21 for the purpose of limiting the range in which each gas is supplied and suppressing an increase in the gas supply amount. By being located as such, in order to prevent the stages 21 and the wafers W from being cooled and to prevent the reactivity of the gas from being lowered, the partition wall forming member 31 is heated to a relatively high temperature of, for example, 150 degrees C. to 180 degrees C. by the partition wall heater 37. Since the partition wall forming member 31 is also made of A5052 as described above, the amount of Mg on the surface of the base material increases when heated to the above temperature. However, since the Si coating film 36, which covers the base material, is formed on the partition walls 34 facing the processing spaces S1 and S2, the generation of Mg(Hfac)₂ from the partition wall forming member 31 by the Hfac gas is suppressed, and the release of the generated Mg(Hfac)₂ gas to the wafers W is suppressed.

Since the shower head 51 is installed to be stacked below the ceiling plate 12 of the processing container 11, the strength of the shower head 51 may be relatively low, and thus the base material of the shower head 51 is made of A1050. Since the shower head 51 is made of A1050, containing almost no Mg, as described above, and has a relatively low temperature, which is the same as that of the ceiling plate 12, during the processing of wafers W as described above, the release of Mg(Hfac)₂ gas from the shower head 51 is suppressed.

Next, the operation of the etching apparatus 1 will be described. For example, after assembling the apparatus, and before processing wafers W, that is, in the state in which no wafer W is loaded into the processing container 11, the stage heater 22, the ceiling heater 13, the side wall heater 15, and the partition wall heater 37 are turned on. Thereby, the ceiling plate 12, the side wall 14, the stage 21, the partition wall forming member 31, and the shower head 51 of the processing container 11 are heated to, for example, 250 degrees C. In the state in which each member is heated as described above, a passivation process of supplying Hfac gas and NO gas into the processing container 11 for, for example, one week, is performed.

Specifically, this passivation process is a process for fluorinating Al on the surface of each member made of A5052 and A1050, such as the inner wall of the processing container 11 and the shower head 51, so as to passivate the Al. As shown in the evaluation tests described below, by performing the passivation process, the release of Al from the above-mentioned members during the processing of a wafer W is suppressed, and the contamination of the wafer W by Al is suppressed. In this passivation process, the reason why NO gas is supplied in addition to the Hfac gas, as described above, is that the contamination of the wafer W with sodium (Na) and potassium (K) is also suppressed by supplying the NO gas in this manner, as shown in the evaluation test.

In the apparatus that has been subjected to the passivation process, a wafer W having a Co film 70 formed on the surface thereof is loaded into the processing container 11 and is mounted on each stage 21. Then, the partition wall forming member 31 moves from the lowered position to the raised position, and the processing spaces S1 and S2 are formed. Meanwhile, the inside of the processing container 11 is exhausted from the exhaust port 45, and a vacuum atmosphere having a desired pressure, for example, 10 kPa to 100 kPa, is formed.

Meanwhile, the stage heater 22, the ceiling heater 13, the side wall heater 15, and the partition wall heater 37 have preset outputs. As a result, the ceiling plate 12, the side wall 14, and the shower head 51 of the processing container 11 reach a temperature in a range of 60 degrees C. to 90 degrees C., as described above. As described above, each stage 21 reaches a temperature of 150 degrees C. to 250 degrees C., and the partition wall forming member 31 reaches a temperature of 150 degrees C. to 180 degrees C. Further, the wafer W mounted on the stage 21 is also heated to the same temperature as the stage 21.

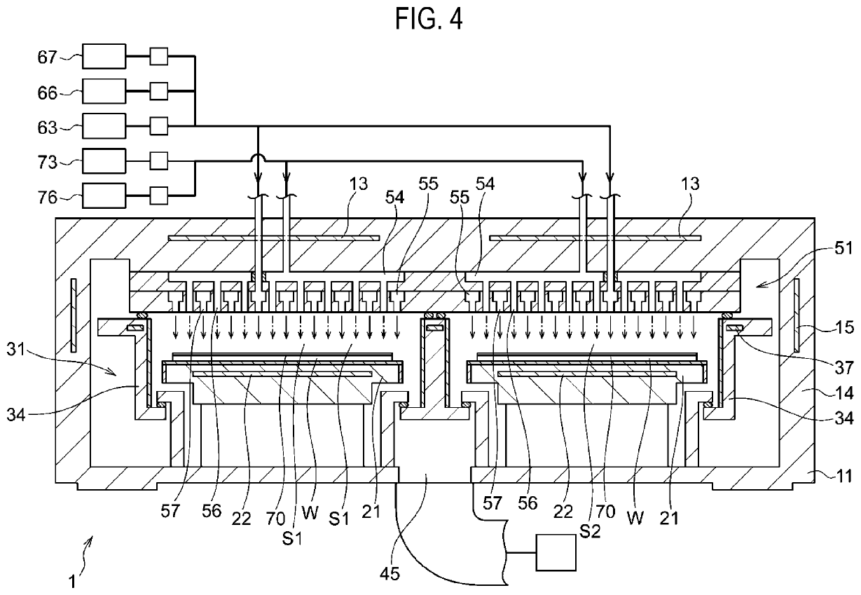

Subsequently, N₂ gas is supplied to the diffusion spaces 54 and 55 in the shower head 51 and is ejected to the processing spaces S1 and S2. Then, H₂ gas is supplied to the diffusion space 54 in addition to the N₂ gas, the H₂ gas is supplied to the processing spaces S1 and S2, and a natural oxide film formed on the surface of the Co film 70 is reduced by the reducing action of H₂. Thereafter, the supply of the H₂ gas to the diffusion space 54 is stopped, NO gas and Hfac gas are supplied to the diffusion space 55 in addition to the N₂ gas, and the NO gas and the Hfac gas are supplied to the processing spaces S1 and S2. As a result, the Co on the surface of the wafer W is oxidized by the NO gas and becomes cobalt oxide (CoO), the CoO forms a complex with the Hfac, and the complex is vaporized by heat. That is, the etching of the Co film proceeds. FIG. 4 illustrates gas flows in the processing container 11 when this etching is performed. The solid-line arrows indicate N₂ gas, NO gas, and Hfac gas ejected from the ejection holes 57 through the diffusion space 55, and the chain-line arrows indicate N₂ gas ejected from the ejection holes 56 through the diffusion space 54.

As described above, during this etching, Mg is suppressed from being turned into Mg(Hfac)₂ gas and released to the wafer W due to the Hfac gas from the wall of the processing container 11 and each member provided in the processing container 11. Thus, the Mg contamination of the wafer W is suppressed. Further, it is possible to suppress the contamination of the wafer W caused by supplying Fe and Ni from the gas supply pipe 61. Thereafter, when the supply of each gas from the shower head 51 is stopped and the etching of the Co film 70 is terminated, the partition wall forming member 31 returns to the lowered position, and the wafer W is unloaded from the processing container 11. As described above, with the etching apparatus 1, the Co film 70 on the surface of the wafer W can be etched while suppressing the contamination of the wafer W caused by each metal, such as Mg, Fe, Ni, Al, Na, or K.

Each of the measures of constituting the shower head 51 using A1050, forming the coating film 36 on the partition wall forming member 31, and providing the top surface cover 23 and the side surface cover 24 on the stage 21 has an effect of suppressing the Mg contamination of the wafer W. That is, by lowering the temperatures of the ceiling plate 12 and the side walls 14 as described above, contamination of the wafer W with Mg is suppressed. However, without performing this temperature control, the effect of suppressing the Mg contamination of the wafer W is also obtained by configuring each of the shower head 51, the partition wall forming member 31, and the stages 21, as described above. Therefore, an etching apparatus, in which the shower head 51, the partition wall forming member 31, or the stage 21 is configured as described above without performing the temperature control, may be adopted.

Then, each of the members described above as being formed using A5052 as a base material, such as the processing container 11, the stages 21 within the processing container 11, and the partition wall forming member 31, may be formed using an Al alloy containing copper (Cu) as a main additive metal, as a base material, instead of A5052. As the Al alloy containing Cu, specifically, for example, a JIS standard A6000 series alloy, more specifically, for example, JIS standard A6061, may be used. Cu reacts with Hfac gas to produce Cu(Hfac)₂, which is a complex. Like the vapor pressure of Mg(Hfac)₂, the vapor pressure of Cu(Hfac)₂ also changes relatively greatly when the temperature changes in the range of 160 degrees C. or lower. Therefore, by controlling the temperature of the wall of the processing container 11 as described above, it is possible to suppress Cu contamination, which may be caused due to the release of Cu(Hfac)₂ gas to the wafers W. Then, by providing covering portions of the top surface cover 23, the side surface cover 24, and the coating film 36, it is possible to suppress the generation of Cu(Hfac)₂ from the stages 21 and the partition wall forming member 31 and the release of Cu(Hfac)₂ gas to the wafers W. That is, when A6061 is used as the base material of each member, it is possible to suppress contamination by Mg and Cu contained in the A6061 by the present technology. The A6000 series base material is not limited to A6061, and A6082 may also be used.

As the A5000 series alloy, for example, A5083 or A5154 may be used, in addition to A5052, and these alloys may be used as a base material, and may be used for each member above-described as using A5052 as a base material instead of A5052. In addition, the A1000 series alloy forming, for example, the shower head 51, is not limited to A1050, and pure aluminum other than A1050, such as A1070 or A1080, may be used.

The base material of the partition wall forming member 31 may be made of, for example, A1050, and the partition wall forming member 31 may have a relatively large thickness so as to ensure high strength and to suppress Mg contamination of the wafer W. However, this increase in thickness may lead to an increase in the size of the partition wall forming member 31 and an increase in the size of the apparatus. Therefore, it is preferable to use A5052.

In addition, regarding the covering portion (coating film 36) that covers the base material of the partition wall forming member 31, it is sufficient if it is possible to suppress the contact between the Hfac gas and the base material of the partition wall forming member 31 and the release of Mg(Hfac)₂ gas from the base material. Therefore, the covering portion is not limited to being made of Si, and may be made of, for example, pure aluminum. In addition, the covering portion for covering the base material in order to prevent the release of the Mg(Hfac)₂ gas in this way may be arbitrarily selected from a film that is inseparable from the base material, such as a vapor-deposited film, and a cover that is separable from the base material. That is, the partition wall forming member 31 may be provided with a cover as a covering portion. In addition, the stages 21 described as being provided with the covers as the covering portion as described above may be covered with a vapor-deposited film instead of providing the covers.

In the shower head 51, as in the partition wall forming member 31, it is possible to suppress the generation of Mg(Hfac)₂ and the release of Mg(Hfac)₂ gas by using A5052 as a base material and forming a vapor-deposited film of, for example, Si, on the surface of the base material as a covering portion for a gas supplier. In that case, for example, the vapor-deposited film of Si is formed on the entire surface of each of the upper plate 52 and the lower plate 53, which constitute the shower head 51. However, since the shower head 51 is provided with a large number of ejection holes 56 and 57, it is difficult to form a vapor-deposited film with sufficient coverage of the base material due to the complicated shape thereof. Thus, the shower head 51 may be configured using A1050, as described above. As described above, for each of the members within the processing container 11, the base material may be configured using A1050, or a configuration in which the base material is made of A5052 and a covering portion is provided to cover the base material may be adopted. It is possible to arbitrarily select either of these configurations.

In the above-described etching apparatus 1, it is not limited to setting both the ceiling wall and the side wall 14 of the processing container 11 to a temperature in a range of 60 degrees C. to 90 degrees C. The temperature of only one of the ceiling wall and the side wall 14 may be set to a temperature in a range of 60 degrees C. to 90 degrees C., and the supply of Mg from the wall of the processing container 11 having the lower temperature to the wafer W may be suppressed. However, both the ceiling wall and the side wall 14 may be set to a temperature in a range of 60 degrees C. to 90 degrees C. in order to more reliably suppress Mg contamination.

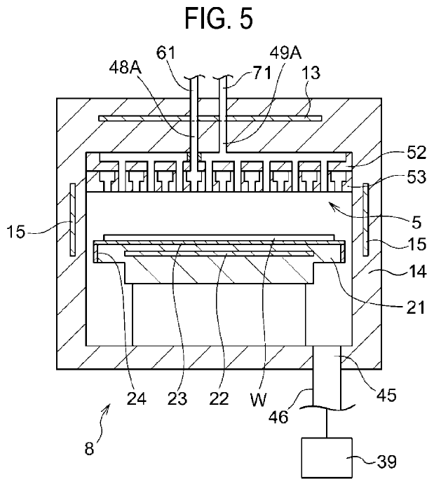

FIG. 5 illustrates an etching apparatus 8, which is another configuration example of the etching apparatus. The etching apparatus 8 will be described mainly with reference to the differences between the etching apparatus 8 and the etching apparatus 1. The etching apparatus 8 is a single-wafer processing apparatus that stores and processes only one wafer W in the processing container 11. The partition wall forming member 31 is not provided, and the side wall 14 of the processing container 11 is located relatively close to a stage 21. Therefore, when the temperature of the side wall 14 is low, the processing of a wafer W is affected. Thus, during the processing of the wafer W, the side wall 14 is heated by the side wall heater 15, for example, to a temperature similar to that of the partition wall forming member 31 of the etching apparatus 1, and then the wafer W is processed. Meanwhile, as in the etching apparatus 1, the ceiling plate 12 is set to a temperature in a range of 60 degrees C. to 90 degrees C. during the processing of a wafer W.

The oxidizing gas is not limited to NO gas, and, for example, oxygen (O₂) gas, ozone (O₃) gas, or nitrous oxide (N₂O) may be used. As the β-diketone gas, which is an etching gas, a gas capable of forming a complex having a vapor pressure lower than that of CoO may be used. For example, a gas such as trifluoroacetylacetone (also called 1,1,1-trifluoro-2,4-pentanedione) or acetylacetone may be used instead of the Hfac gas. However, after the side wall 14 and the ceiling plate 12 of the processing container 11 are controlled to a temperature in a range of 60 degrees C. to 90 degrees C. as described above, a gas that is not liquefied or solidified by the pressure inside the processing container 11 is used.

The metal film to be etched is not limited to the Co film, and may be a film made of, for example, manganese (Mn), zirconium (Zr), or hafnium (Hf). Further, the oxidizing gas and the etching gas are not limited to being supplied into the processing container 11 at the same time, and the etching gas may be supplied after the supply of the oxidizing gas is terminated. In that case, when the etching gas is supplied to the wafer W, the wall of the processing container 11 may be set to a temperature in a range of 60 degrees C. to 90 degrees C., as described above. Further, when the oxidizing gas is supplied, the wall may be set to a temperature out of this temperature range.

The gas supplier is not limited to being constituted with the shower head 51. For example, a configuration in which gas is supplied to the processing spaces S1 and S2 from slits formed in the ceiling wall that constitutes the gas supplier may be adopted. In the etching apparatus 8, a nozzle may be installed as a gas supplier at a position spaced apart from the ceiling wall, and gas may be supplied into the processing container 11 from the nozzle. Therefore, the gas supplier is not limited to forming the ceiling wall of the processing container 11. In that case, for example, among the gas supplier and the ceiling plate 12, only the ceiling plate 12 may be controlled to the above-mentioned temperature so as to process the wafer W.

The above-mentioned passivation process may be performed using a gas containing fluorine other than Hfac gas, for example, HF gas, F₂ gas, or CF₄ gas, as long as the gas can passivate Al. The passivation process may be performed before the apparatus is assembled, that is, in the state in which the respective members are not joined to each other. However, in order to simplify processing, it is preferable to perform the passivation process by supplying gas into the processing container after the apparatus is assembled, as described above.

It should be understood that the embodiments disclosed herein are illustrative and are not restrictive in all aspects. The above-described embodiments may be omitted, replaced, or modified in various forms, or may be combined with each other, without departing from the scope and spirit of the appended claims.

### (Evaluation Test)

Hereinafter, descriptions will be made on evaluation experiments, which were performed in connection with the present disclosure.

### (Evaluation Test 1)

As Evaluation Test 1-1, a wafer W was loaded into an etching apparatus for testing. The etching apparatus for testing differs from the etching apparatus 1 in that the gas supply pipe 61 through which Hfac gas flows is made of SUS and the shower head 51 is made of A5052. In addition, a Si coating film 36 of the partition wall forming member 31 and the top surface cover 23 made of Si of the stage 21 are not provided, and the side surface cover 24 is made of A5052. That is, this etching apparatus for testing does not have a structure for suppressing the contamination of a wafer W caused by Mg, Fe, and Ni described in the embodiments. Hfac gas, NO gas, and N₂ gas were ejected from the ejection holes 57 in the shower head 51 to the wafer W loaded into the etching apparatus for testing, and N₂ gas was ejected from the ejection holes 56 in the shower head 51 so as to etch the Co film on the surface of wafer W. During this etching, the ceiling plate 12 and the shower head 51 were heated to 130 degrees C., and the side wall 14 was heated to 125 degrees C. Thereafter, using inductively coupled plasma mass spectrometry (ICP-MS), the areal density of each existing metal was measured on the surface of the wafer W after the etching process.

Further, as Evaluation Test 1-2, the same test as Evaluation Test 1-1 was performed, except that only N₂ gas was supplied from the ejection holes 56 to the wafer W loaded into the etching apparatus for testing, and the areal densities of metals on the surface of the wafer W were measured. In addition, as Evaluation Test 1-3, the same test as in Evaluation Test 1-1 was performed, except that only N₂ gas was supplied from the ejection holes 57 to the wafer W loaded into the etching apparatus for testing, and the areal densities of contamination metals on the surface of the wafer W were measured. Regarding the measured areal density of each metal, 100×E+10 atoms/cm² or less (1×E+12 atoms/cm²) is an allowable range, and 5×E+10 atoms/cm² is particularly preferable for practical use. Hereinafter, 100×E+10 atoms/cm² may be described as an allowable value and 5×E+10 atoms/cm² may be described as a target value.

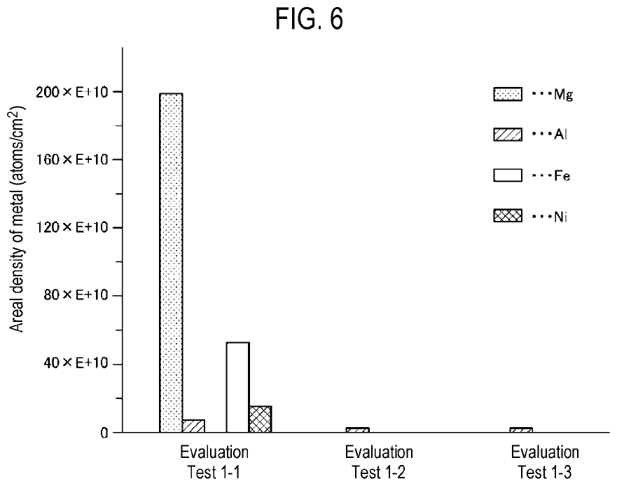

The bar graph in FIG. 6 shows the areal density (unit: atoms/cm²) of each metal detected in Evaluation Tests 1-1 to 1-3. As shown in this graph, Al was detected in Evaluation Tests 1-2 and 1-3, but the areal density thereof was lower than 5×E+10 atoms/cm². Meanwhile, in Evaluation Test 1-1, the areal density of Al was slightly higher than 5×E+10 atoms/cm², but was not much different from the values in Evaluation Tests 1-2 and 1-3. The areal densities of Mg, Fe, and Ni were almost zero in Evaluation Tests 1-2 and 1-3, but in Evaluation Test 1-1. However, the areal densities of Mg, Fe, and Ni were 200E+10 atoms/cm², 50E+10 atoms/cm², and 15E+10 atoms/cm², respectively. Therefore, from the results of Evaluation Test 1, it is estimated that the wafer W was contaminated with Mg, Fe, and Ni due to the Hfac gas. In Evaluation Test 1-1, metals such as Na, Mn, and Cu were also detected, but the areal densities thereof are not indicated in the graph of FIG. 6 because the areal densities were insignificant.

### (Evaluation Test 2)

As Evaluation Test 2-1, a wafer W was loaded into a newly manufactured etching apparatus for testing, and an etching process was performed in the same manner as in Evaluation Test 1-1. The etching apparatus 1 for testing was not subjected to the passivation process described in the embodiments. Then, with respect to the surface of the processed wafer W, the areal density of each metal was measured as in Evaluation Test 1-1.

As Evaluation Test 2-2, a passivation process was performed on a newly manufactured etching apparatus for testing. This passivation process was performed by continuously supplying Hfac gas into the processing container 11 for 14 hours while each of the side wall heater 15, the ceiling heater 13, the stage heater 22, and the partition wall heater 33 was set to 220 degrees C. After the passivation process, a wafer W was subjected to an etching process using this etching apparatus for testing, and the areal density of each metal was measured for the wafer W in the same manner as in Evaluation Test 2-1. As Evaluation Test 2-3, the same test as Evaluation Test 2-2 was performed, except that the passivation process was performed by supplying Hfac gas and NO gas, and the passivation process was performed for 24 hours. Further, as Evaluation Test 2-4, the same test as Evaluation Test 2-3 was performed, except that the passivation process was performed for 1 week in the state in which the temperature of each of the above-mentioned heaters was set to 250 degrees C.

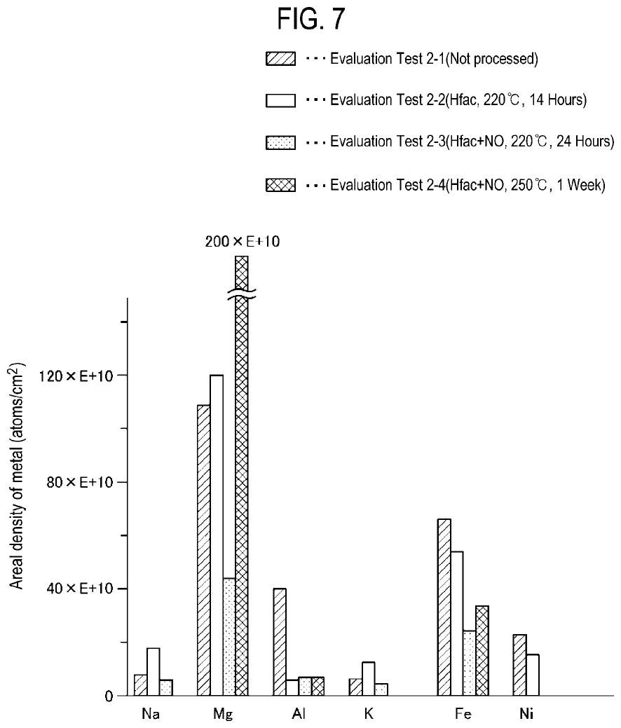

The bar graph in FIG. 7 shows the areal density (unit: atoms/cm²) of each metal detected in Evaluation Tests 2-1 to 2-4. The results for Cr, Mn, Cu, and Zn, the areal densities of which were smaller than 5×E+10 atoms/cm², are omitted for convenience of illustration. Regarding Al, referring to the graph of FIG. 7, Evaluation Test 2-1 showed 40×E+10 atoms/cm², but Evaluation Tests 2-2 to 2-4 showed about 5×E+10 atoms/cm². Therefore, it was confirmed that Al contamination of the wafer W can be effectively suppressed by the passivation process. Regarding Na, Evaluation Tests 2-1 and 2-2 showed values larger than 5×E+10 atoms/cm², but Evaluation Test 2-3 showed about 5×E+10 atoms/cm² and Evaluation Test 2-4 showed about zero. Regarding K, Evaluation Tests 2-1 and 2-2 showed values larger than 5×E+10 atoms/cm², but Evaluation Test 2-3 showed a value smaller than 5×E+10 atoms/cm² and Evaluation Test 2-4 showed about zero. Therefore, in order to sufficiently reduce contamination by Na and K in addition to contamination by Al, it can be seen that it is effective to use the NO gas in addition to the Hfac gas for the passivation process, and to perform the passivation process for a sufficiently long time. Thus, the passivation process is performed, preferably, for 24 hours or more, and more preferably, for 1 week. In Evaluation Test 2-2 in which the inside of the processing container 11 was exposed to Hfac gas for 14 hours as described above, the areal density of Al was suppressed to the target value. Even if the time of exposure to the Hfac gas is slightly shorter than 14 hours, it is considered that the areal density of Al can be suppressed to the target value. Thus, it is considered that the time of exposure to the Hfac gas is preferably 12 hours or more.

Regarding Ni and Fe, which form SUS used in the gas supply pipe 61, for Ni, Evaluation Tests 2-1 and 2-2 showed relatively high areal densities, but Evaluation Tests 2-3 and 2-4 showed areal densities of about zero. However, for Fe, Evaluation Tests 2-2 to 2-4 showed relatively high values of 20×E+10 atoms/cm² or more, even though the values were lower than in Evaluation Test 2-1. Thus, it can be seen that the areal density of Fe was not sufficiently suppressed by the passivation process. Therefore, it is considered that it is effective to configure the gas supply pipe 61 using Hastelloy instead of SUS as in the above-described embodiments.

Regarding Mg, all of Evaluation Tests 2-1 to 2-4 showed high areal densities of 40×E+10 atoms/cm² or more, and among Evaluation Tests 2-1 to 2-4, Evaluation Test 2-4 in which the passivation process was performed for the longest time showed the highest areal density of 200×E+10 atoms/cm². Therefore, in order to suppress Mg contamination of the wafer W, it was confirmed that another measure other than the passivation process is necessary.

### (Evaluation Test 3)

As Evaluation Test 3-1, the volume density of Mg in the depth direction was measured for samples made of A5052 using X-ray photoelectron spectroscopy (XPS). The samples used in Evaluation Test 3-1 were not subjected to heat treatment before measurement. As Evaluation Test 3-2, the same test as Evaluation Test 3-1 was performed, except that the samples were heat-treated at 130 degrees C. before measurement using XPS. In addition, as Evaluation Test 3-3, the same test as Evaluation Test 3-1 was performed, except that the samples were heat-treated at 250 degrees C. before measurement using XPS.

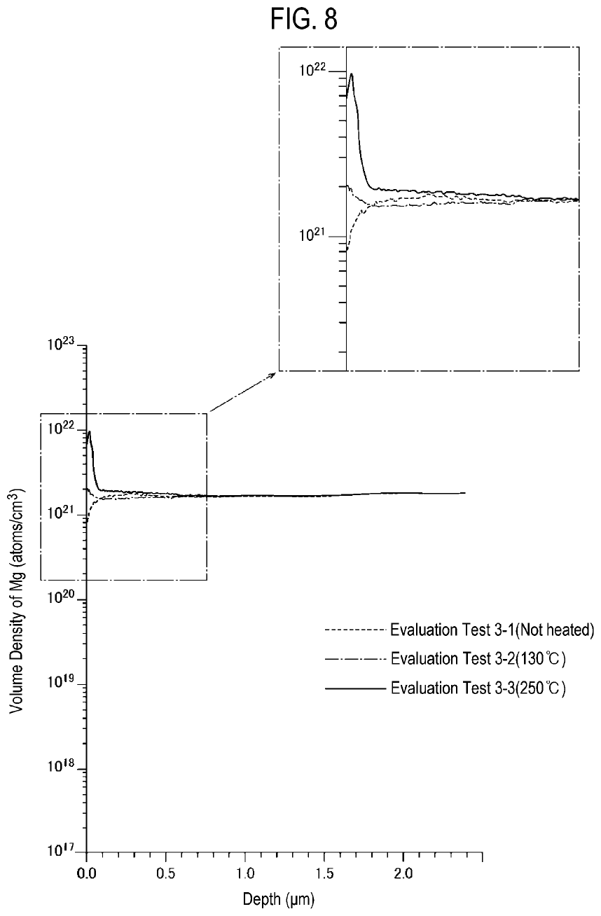

The graph of FIG. 8 shows the results of Evaluation Test 3, in which the vertical axis represents the volume density of Mg (unit: atoms/cm³) and the horizontal axis represents the depth of a sample (unit: μm). The results near the depth of 0 μm to 0.5 μm are enlarged and shown in the upper-right portion of the figure. As shown in the graph of FIG. 8, in Evaluation Test 3-1, the volume density of Mg near the depth of 0 μm to 1 μm, which is an outermost layer of the sample, is smaller than the volume density of Mg at a deeper position. However, in Evaluation Test 3-2, the volume density of Mg in the outermost layer is slightly greater than that at a deeper position, and in Evaluation Test 3-3, the volume density of Mg in the outermost layer is greater than that at a deeper position. That is, it is considered that when a sample is heated, Mg moves from the inside of the sample to the outermost layer, and it can be seen that the higher the heating temperature, the higher the volume density of Mg in the outermost layer.

From the results of Evaluation Test 3, it can be seen that in order to suppress the Mg contamination of a wafer W, it is effective to set the temperature of a member made of A5052 to a relatively low temperature. That is, as described in the embodiments, it is considered that it is effective to perform the etching process by setting the ceiling wall and the side wall 14 of the processing container 11 to a relatively low temperature. Further, it is considered that it is effective to cover the surface of the base material composed of A5052 in the processing container or to make a member in the processing container 11 using a material having a low Mg content, such as A1050, instead of A5052.

### (Evaluation Test 4)

In the above-described etching apparatus for testing, an etching process was performed on a wafer W as illustrated in the embodiments while changing the combination of the temperature of the ceiling wall of the processing container 11 and the temperature of the side wall 14 of the processing container 11. Then, with respect to the processed wafer W, the areal density of each metal was measured as in Evaluation Test 1. As Evaluation Test 4-1, the process was performed by setting the temperature of the ceiling wall to 80 degrees C. and the temperature of the side wall 14 to 80 degrees C. As Evaluation Test 4-2, the process was performed by setting the temperature of the ceiling wall to 100 degrees C. and the temperature of the side wall 14 to 100 degrees C. As Evaluation Test 4-3, the process was performed by setting the temperature of the ceiling wall to 130 degrees C. and the temperature of the side wall 14 to 125 degrees C.

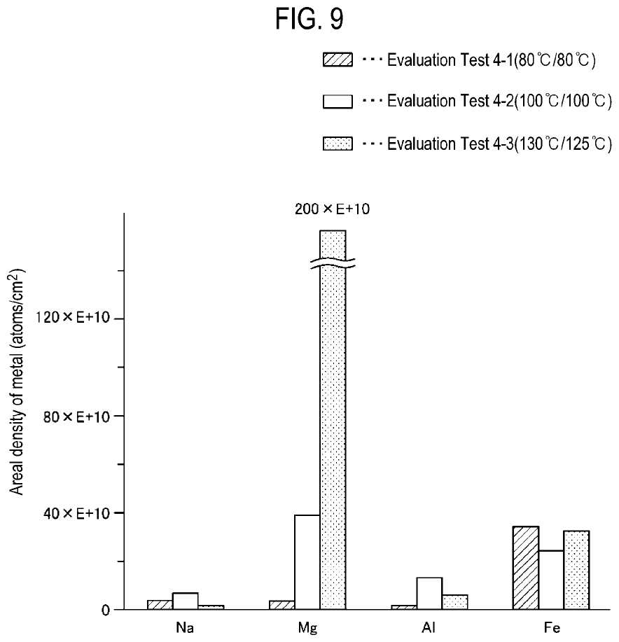

The bar graph in FIG. 9 shows the areal density (unit: atoms/cm²) of each metal detected in Evaluation Test 4. In the graph, among the measured metals Na, Mg, Al, K, and Fe, the metal K, which showed a value below the target value in each of Evaluation Tests 4-1 to 4-3, is omitted for convenience of illustration. Regarding Mg, Evaluation Test 4-3 showed a value of 200×E+10 atoms/cm², but Evaluation Test 4-2 showed a value of 40×E+10 atoms/cm², and Evaluation Test 4-1 showed a value lower than 5×E+10 atoms/cm². Therefore, it was confirmed that when the temperature of the ceiling wall and the side wall 14 is set to 80 degrees C. or lower, the contamination of the wafer W by Mg can be effectively suppressed. Regarding Mg, the results of Evaluation Test 4 showed values that exceed the target value of 5×E+10 atoms/cm² at 100 degrees C. of the ceiling wall and the side wall 14, but become smaller than 5×E+10 atoms/cm² at 80 degrees C. of the ceiling wall and the side wall 14. Therefore, it is considered that it is effective to set the temperature to 90 degrees C. or less, as illustrated in the embodiments, since, even if the temperature is higher than 80 degrees C. and lower than 100 degrees C., the areal density of Mg can be 5 atoms/cm² or less.

### (Evaluation Test 5)

Evaluation Test 5 was performed using an apparatus for testing. The apparatus for testing includes a processing container made of A1050, a gas supply pipe for supplying N₂ gas and Hfac gas into the processing container, an exhaust pipe for exhausting the processing space in the processing container, and a storage for storing solid Hfac. The pipes are configured such that while the N₂ gas flows in the gas supply pipe, the N₂ gas is mixed with the Hfac gas vaporized in the storage container and supplied to the gas supply pipe, and the mixed gas is supplied to the processing container. The processing container includes a hot plate that heats a wafer W and forms a bottom wall of the processing container, and a cover that is provided on the hot plate and forms the side wall and the ceiling wall of the processing container. The wafer W is placed on pins provided on the surface of the hot plate. The downstream side of the gas supply pipe, the storage container, and the upstream side of the exhaust pipe are made of perfluoroalkoxyalkane (PFA) or polytetrafluoroethylene (PTFE). As described above, the apparatus for testing was configured so that metal does not flow into the processing container from the gas supply pipe and the exhaust pipe.

Test plates were mounted on the lower side of the ceiling wall of the processing container and right above the hot plate. Then, in the state in which a silicon wafer W was placed on the hot plate and heated to 200 degrees C. and the pressure inside the processing container was set to 50 Torr (6.67×10³ Pa) by exhaust, N₂ gas was supplied at 100 sccm for 1 minute. In addition, Hfac gas was supplied to the wafer W together with the N₂ gas as described above. The areal density of Mg was measured on the surface of the wafer W processed in this manner. The test plates mounted on the ceiling wall and the hot plate were changed to other test plates having different configurations each time when the process was performed.

Tests executed using plates made of A1050 and plates made of A5052 as the test plates are referred to as Evaluation Tests 5-1 and 5-2, respectively. The base materials of A1050 and A5052 were exposed on the surfaces of the plates used in Evaluation Tests 5-1 and 5-2, respectively. In addition, a test executed using plates made of A5052 and having a surface coated with a pure aluminum film having a thickness of 1 μm as the above-mentioned test plate is referred to as Evaluation Test 5-3. Further, a test executed using plates made of A5052 and having a surface coated with a pure aluminum film having a thickness of 10 μm is referred to as Evaluation Test 5-4, and a test executed using a plate made of A5052 and having a surface coated with a vapor-deposited film of Si having a thickness of 1 μm are referred to as Evaluation Test 5-5.

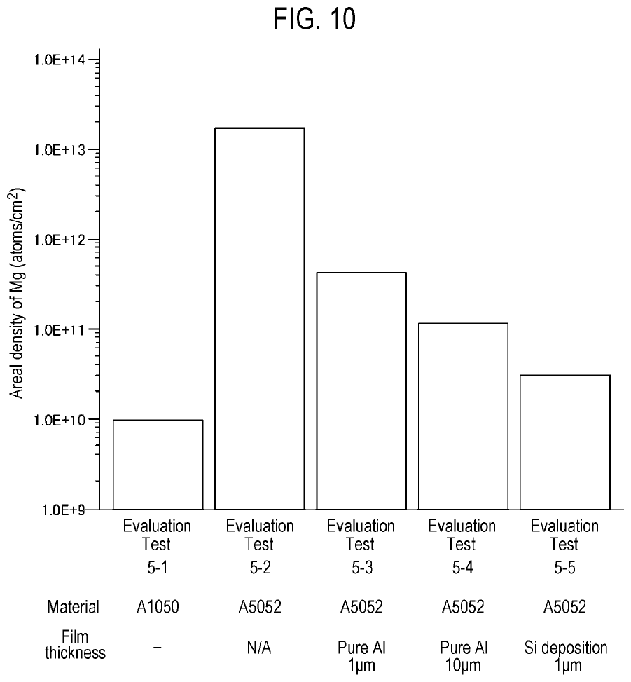

The bar graph in FIG. 10 shows the areal density (unit: atoms/cm²) of Mg detected in Evaluation Test 5. As shown in this graph, compared with the areal density of Mg in Evaluation Test 5-2 using the plates made of A5052 and not coated with a film of pure aluminum or Si, the areal densities of Mg of Evaluation Tests 5-1, and 5-3 to 5-5 are low. Therefore, it can be seen that it is possible to suppress Mg contamination of wafers by covering the members made of A5052 in the above-described processing containers with members made of pure aluminum or Si or by making the members in the processing containers using A1050.

In particular, in Evaluation Tests 5-1 and 5-5, the areal densities of Mg of the wafers W are low. Therefore, it can be seen that the shower head 51 made of A1050, the stage 21 covered with the top surface cover 23 of Si and the side surface cover 24 of A1050, and the partition wall forming member 31 provided with the Si coating film 36 described in the embodiments are preferable structures for suppressing Mg contamination of wafers W. In Evaluation Tests 5-1 and 5-5, the areal densities of Mg in Evaluation Test 5-1 are lower. Therefore, it can be seen that the shower head 51 and the side surface cover 24 of the stage 21 made of pure aluminum as described in the embodiments are more preferable structures.

### (Evaluation Test 6)

Wafers W were sequentially transported to the etching apparatus 1, and the etching process was performed as described in the embodiments. Regarding the wafer W that has been subjected to the 10th process, the wafer W that has been subjected to the 20th process, and the wafer W that has been subjected to the 30th process, areal surface densities of respective metals on the surfaces of the wafers were measured as Evaluation Test 6-1, 6-2, and 6-3, respectively, in the same manner as in Evaluation Test 1.

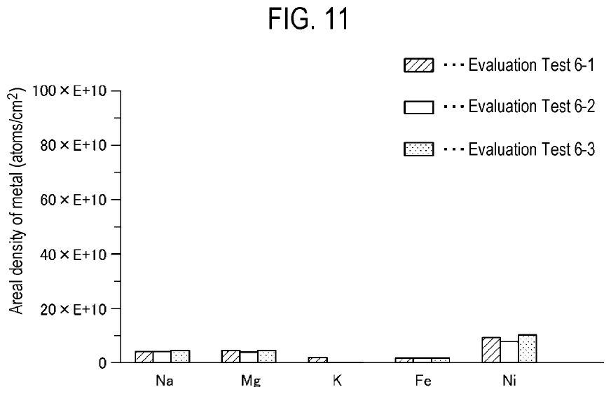

The bar graph in FIG. 11 shows the areal density (unit: atoms/cm²) of each metal detected in Evaluation Test 6. The detected areal densities of Na, Mg, Al, K, Cr, Fe, Cu, Zn, and Mo were equal to or lower than the target values in Evaluation Tests 6-1 to 6-3. Since the areal densities of Al, Cr, Cu, and Zn were substantially zero in Evaluation Tests 6-1 to 6-3, an illustration thereof is omitted. Regarding Ni, the values in Evaluation Tests 6-1 to 6-3 are much lower than the permissible value and smaller than the value obtained using the apparatus for testing in Evaluation Test 1-1. Therefore, it was confirmed that various metal contaminations on wafers W can be suppressed by the etching apparatus 1 described above.

According to the present disclosure, when etching a metal film formed on a substrate using a gas that is β-diketone, it is possible to prevent metal contamination of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching apparatus comprising:
a processing container configured to form a vacuum atmosphere in the processing container when evacuated and including a wall constructed using an alloy composed of aluminum and an additive metal as a base material of the wall of the processing container;
a stage installed in the processing container and configured to mount a substrate having a metal film formed on a surface of the substrate;
a gas supplier installed in the processing container and configured to supply an oxidizing gas that oxidizes the metal film and an etching gas that is β-diketone to the stage to etch the oxidized metal film; and
a wall heater configured to heat the wall to a temperature in a range of 60 degrees C. to 90 degrees C. when the etching gas is supplied from the gas supplier into the processing container.

2. The etching apparatus of claim 1, wherein the wall heated by the wall heater includes a ceiling wall of the processing container.

3. The etching apparatus of claim 2, wherein a plurality of stages is installed,
the etching apparatus further comprises a partition wall extending downward from the ceiling wall and surrounding each of the plurality of stages, and a partition wall heater configured to heat the partition wall,
the gas supplier forms the ceiling wall and is configured to supply the etching gas and the oxidizing gas to a processing space surrounded by the partition wall, and
the wall heated by the wall heater includes the ceiling wall and a side wall of the processing container.

4. The etching apparatus of claim 3, wherein a base material of the partition wall is an alloy composed of aluminum and an additive metal, and
an inner wall surface of the partition wall is constituted with a covering portion for the partition wall that covers the base material of the partition wall so as to prevent the additive metal of the base material of the partition wall from being released to the substrate.

5. The etching apparatus of claim 4, wherein the base material of the partition wall is one of a JIS standard A5000 series alloy or A6000 series alloy, and
the covering portion for the partition wall is made of silicon.

6. The etching apparatus of claim 5, wherein a base material of the gas supplier is made of one of a JIS standard A5000 series alloy or a JIS standard A6000 series alloy, and is provided with a covering portion for the gas supplier that covers a surface of the base material of the gas supplier so as to prevent release of an additive metal of the base material of the gas supplier to the substrate, or
the base material of the gas supplier is made of a JIS standard A1000 series material.

7. The etching apparatus of claim 6, wherein the gas supplier is a shower head, and the base material of the gas supplier is made of the JIS standard A1000 series material.

8. The etching apparatus of claim 7, wherein a base material of the stage is an alloy composed of aluminum and an additive metal, and
a top surface and a side surface of the stage are constituted with a stage covering portion that covers the base material of the stage so as to prevent the additive metal of the base material of the stage from being released to the substrate.

9. The etching apparatus of claim 8, wherein the base material of the stage is one of a JIS standard A5000 series alloy or A6000 series alloy, and
wherein the stage covering portion includes:
a top surface covering portion made of silicon to cover the top surface of the stage; and
a side surface covering portion made of a JIS standard A1000 material to cover the side surface of the stage.

10. The etching apparatus of claim 9, wherein the base material of the wall of the processing container is one of a JIS standard A5000 series alloy or A6000 series alloy.

11. The etching apparatus of claim 10, wherein the base material of the wall of the processing container is JIS standard A5052.

12. The etching apparatus of claim 11, further comprising:
an etching gas reservoir configured to store the etching gas outside the processing container; and
a flow path formation portion connecting the etching gas reservoir and the processing container to form a flow path, and configured to supply the etching gas to the gas supplier,
wherein the flow path formation portion is made of Hastelloy.

13. The etching apparatus of claim 12, wherein the etching gas is hexafluoroacetylacetone gas.

14. The etching apparatus of claim 1, wherein a base material of the gas supplier is made of one of a JIS standard A5000 series alloy or a JIS standard A6000 series alloy, and is provided with a covering portion for the gas supplier that covers a surface of the base material of the gas supplier so as to prevent release of an additive metal of the base material of the gas supplier to the substrate, or
the base material of the gas supplier is made of a JIS standard A1000 series material.

15. The etching apparatus of claim 1, wherein a base material of the stage is an alloy composed of aluminum and an additive metal, and
a top surface and a side surface of the stage are constituted with a stage covering portion that covers the base material of the stage so as to prevent the additive metal of the base material of the stage from being released to the substrate.

16. The etching apparatus of claim 1, wherein the base material of the wall of the processing container is one of a JIS standard A5000 series alloy or A6000 series alloy.

17. The etching apparatus of claim 1, further comprising:
an etching gas reservoir configured to store the etching gas outside the processing container; and
a flow path formation portion connecting the etching gas reservoir and the processing container to form a flow path, and configured to supply the etching gas to the gas supplier,
wherein the flow path formation portion is made of Hastelloy.

18. The etching apparatus of claim 1, wherein the etching gas is hexafluoroacetylacetone gas.

19. An etching method comprising:
forming a vacuum atmosphere by evacuating an inside of a processing container having a wall that has a base material of which is an alloy made of aluminum and an additive metal;
mounting a substrate, having a metal film formed on a surface of the substrate, on a stage installed the processing container;
supplying an oxidizing gas that oxidizes the metal film and an etching gas that is β-diketone to the stage from a gas supplier installed in the processing container so as to etch the oxidized metal film; and
heating the wall to a temperature in a range of 60 degrees C. to 90 degrees C. when the etching gas is supplied from the gas supplier into the processing container by a wall heater.

20. The etching method of claim 19, further comprising:
exposing the inside of the processing container to a gas containing fluorine for 12 hours or longer before processing the substrate.
